(19) United States
(12) Patent Application Publication
(10) Pub. No.: US 2012/0142265 A1
(43) Pub. Date: Jun. 7, 2012

(54) CONTAINER DATA CENTER

(75) Inventor: CHAO-KE WEI, Tu-Cheng (TW)

(73) Assignee: HON HAI PRECISION INDUSTRY CO., LTD., Tu-Cheng (TW)

(21) Appl. No.: 12/981,553

(22) Filed: Dec. 30, 2010

(30) Foreign Application Priority Data
Dec. 7, 2010 (TW) 99142703

(51) Int. Cl. H05K 5/03; F24F 7/00

(52) U.S. Cl. 454/184; 454/237; 454/289

(57) ABSTRACT

A container data center includes a container and a number of server systems arranged in two rows. The container includes a top wall, a bottom wall opposite to the top wall, and opposite sidewalls connected between the top wall and the bottom wall. Each of the sidewalls defines an intake adjacent to the bottom wall of the container, and an outlet adjacent to the top wall of the container. Air outside the container is drawn into the container through the intake to cool the server systems. Hot air dissipated by the server systems is exhausted out of the container through the outlet of the container.

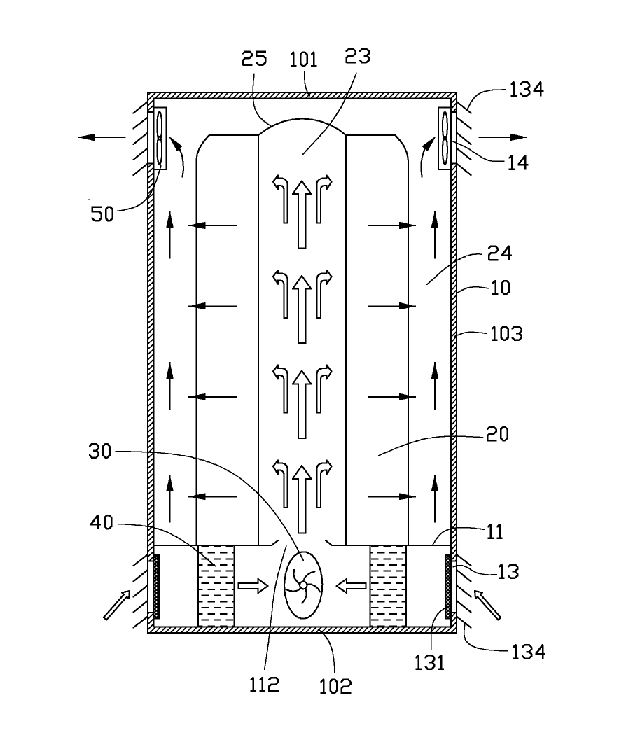

### CROSS-REFERENCE OF RELATED APPLICATION

Relevant subject matter is disclosed in a pending U.S. patent application, titled “CONTAINER DATA CENTER AND HEAT DISSIPATION SYSTEM” with the application Ser. No. 12/894,173, filed on Sep. 30, 2010, which is assigned to the same assignee as this patent application.

### BACKGROUND

1. Technical Field

The present disclosure relates to data centers, and particularly to a container data center.

2. Description of Related Art

With increasing heavy duty use of on-line applications, the need for computer data centers has increased rapidly. Data centers are centralized computing facilities that include many servers, often arranged on server racks or shelves, and one rack or shelf with some servers can be considered a server system. During operation, server systems generate a lot of heat in the data centers, and a common method for dissipating the heat is to use air conditioners, which are very expensive to purchase and operate. Therefore an energy-saving heat dissipation system is needed.

### BRIEF DESCRIPTION OF THE DRAWING

Many aspects of the present embodiments can be better understood with reference to the following drawing. The components in the drawing are not necessarily drawn to scale, the emphasis instead being placed upon clearly illustrating the principles of the present embodiments.

The FIGURE is a cross-sectional, schematic view of an embodiment of a container data center.

### DETAILED DESCRIPTION

The disclosure, including the accompanying drawing, is illustrated by way of example and not by way of limitation. It should be noted that references to “an” or “one” embodiment in this disclosure are not necessarily to the same embodiment, and such references mean at least one.

Referring to the FIGURE, an embodiment of a container data center includes a mobile container 10 and a plurality of server systems 20 installed in the container 10. The server systems 20 are arranged in two parallel rows.

The container 10 includes a top wall 101, a bottom wall 102 opposite to the top wall 101, opposite sidewalls 103 substantially perpendicularly connected between sides of the top wall 101 and the bottom wall 102, and a raised floor 11 parallel and close to the bottom wall 102. Each of the sidewalls 103 defines an intake 13 arranged under the raised floor 11, and an outlet 14 adjacent to the top wall 101. The server systems 20 are supported on the raised floor 11. A heat shield 25 is connected between tops of the corresponding server systems 20 in the two rows. In the container 10, there is a cold aisle 23 defined among the server systems 20, the heat shield 25, and the raised floor 11, and a hot aisle 24 defined among the sidewalls 103 of the container 10, the server systems 20, the heat shield 25, and the raised floor 11. The raised floor 11 defines an opening 112 communicating with the cold aisle 23.

The container data center further includes an air input device 30, two heat exchangers 40, and two air exhaust devices 50. The air input device 30 is received in the container 10, and arranged under the raised floor 11. In one embodiment, the air input devices 30 are axial fans, each including an air duct (not shown) aligned with the opening 112 of the raised floor 11. The air exhaust devices 50 are respectively attached to the sidewalls 103 of the container 10, and aligned with the outlets 14 of the container. The heat exchangers 40 are received in the container 10, and arranged under the raised floor 11, between the air input devices 30 and the corresponding intakes 13 of the container 10.

In use, air outside of the container 10 is drawn into the container 10 through the intakes 13 by the air input devices 30. The air flows through the heat exchangers 40 to be cooled, and then the cooled air is guided into the cold aisle 23 by the air input devices 30. The server systems 20 draw in the cooled air from the cold aisle 23, and dissipate hot air into the hot aisle 24. The hot air in the hot aisle 24 flows up, and is exhausted out of the container 10 through the outlets 14 by the air exhaust devices 50. When the ambient temperature of the container 10 is low enough, the heat exchangers 40 may be shut down for power conservation. Because natural convection forces hot air to flow up to the outlets 14, some power for driving the air can be saved, and because the air outlets 14 are defined in the sidewalls 103 of the container 10, the server systems 20 can be as tall as possible to make full use of the inner height of the container 10 without interfering with the airflow.

In one embodiment, two air filters 131 are respectively attached to the sidewalls 103 of the container 10 to correspondingly cover the intakes 13, thereby preventing dust entering the container 10. A plurality of rain shields 134, such as louvered windows, are attached to sidewalls 103 of the container 10 to respectively cover the intakes 13 and the outlets 14, thereby preventing water from entering the container 10.

It is to be understood, however, that even though numerous characteristics and advantages of the embodiments have been set forth in the foregoing description, together with details of the structure and function of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A container data center comprising:
a mobile container comprising a top wall, a bottom wall opposite to the top wall, and opposite sidewalls connected between the top wall and the bottom wall; and
a plurality of server systems installed in the container, and arranged in two parallel rows;
wherein an intake is defined in one of the sidewalls of the container adjacent to the bottom wall of the container; an outlet is defined in one of the sidewalls of the container adjacent to the top wall of the container; air outside the container is drawn into the container through the intake of the container to cool the server systems, hot air dissipated by the server systems is exhausted out of the container through the outlet of the container.

2. The container data center of claim 1, further comprising an air input device to draw the air outside the container into the container, a heat exchanger to cool the air flowing into the container, and an air exhaust device to drive the hot air inside the container out of the container through the outlet.

3. The container data center of claim 2, wherein the air input device is attached to said one of the sidewalls of the container defining the intake, and aligned with the intake.

4. The container data center of claim 2, wherein the container further comprises a raised floor parallel and close to the bottom wall of the container, the raised floor supports the server systems, and defines an opening therein, the intake of the container is arranged under the raised floor, the air exhaust device is received in the container, arranged under the raised floor, and aligned with the opening of the raised floor.

5. The container data center of claim 4, wherein the heat exchanger is received in the container, and arranged under the raised floor, between the intake of the container and the air exhaust device.

6. The container data center of claim 4, wherein a heat shield is connected between tops of the server systems, a cold aisle is defined among the server systems, the heat shield, and the raised floor, a hot aisle is defined among the sidewalls of the container, the server systems, the heat shield, and the raised floor, the opening of the raised floor communicates with the cold aisle.

7. The container data center of claim 1, wherein two rain shields are attached to the container to respectively cover the air intake and the air outlet, thereby preventing water from entering the container.

8. The container data center of claim 1, wherein an air filter is mounted to the container to cover the intake of the container.
